(19) United States
(12) Patent Application Publication
(10) Pub. No.: US 2013/0324414 A1
(43) Pub. Date: Dec. 5, 2013

(54) SOLID-STATE CATALYSIS OF SUPERCONDUCTING CUPRATES

(71) Applicants: Vyacheslav F. Solovyov, Rocky Point, NY (US); Qiang Li, Setauket, NY (US)

(72) Inventors: Vyacheslav F. Solovyov, Rocky Point, NY (US); Qiang Li, Setauket, NY (US)

(73) Assignee: BROOKHAVEN SCIENCE ASSOCIATES, LLC, Upton, NY (US)

(21) Appl. No.: 13/814,284

(22) PCT Filed: Aug. 4, 2011
(86) PCT No.: PCT/US11/46554

§ 371 Date: Aug. 15, 2013

Related U.S. Application Data
(60) Provisional application No. 61/371,438, filed on Aug. 6, 2010.

(51) Int. Cl. H01L 39/12; H01L 39/24

(52) U.S. Cl. CPC H01L 39/126; H01L 39/2464; H01L 39/2422
USPC 505/126; 505/125; 505/470; 252/519.1; 423/263

(57) ABSTRACT

Catalytically active (001) ceria substrates or buffers are used to modify the structure of the epitaxial high temperature superconductor YBa₂Cu₃O₇. The catalytically active substrate has a small lateral grain size, typically less than 50 nm, to provide a high density of nucleation sites, at some of which nucleate a previously unknown metastable phase. The modification is achieved by catalytically assisted synthesis of the metastable phase. The new phase, a long-period (3.5-nm) perovskite, intercalates into the YBa₂Cu₃O₇ matrix without negatively affecting the critical temperature of the film. Analysis of electron microscopy and synchrotron X-ray diffraction data allow identification of the phase as a long-period YBa₂Cu₃O₇ derivative formed through short-range cation displacement. The films, from about 100-nm to about 1000-nm thick, exhibit strong enhancement of the critical current density, reaching a maximum of approximately 4.2 MA/cm² at 77 K.

This invention was made with Government support under contract number DE-AC02-98CH10886, awarded by the U.S. Department of Energy. The Government has certain rights in the invention.

### FIELD OF THE INVENTION

The invention relates to the solid-state catalysis of nucleation and growth of metastable phases of superconducting cuprates. In particular, it relates to second generation (2G) high-temperature superconductors (HTS) having improved properties.

### BACKGROUND

Since its discovery in the late 1980's, yttrium barium copper oxide YBa₂Cu₃O₇ (YBCO) has been considered as one of the most promising crystalline chemical compounds that can function as high-temperature superconductors (HTS) after achieving superconductivity above the boiling point (77 K) of liquid nitrogen. High temperature superconductors (HTS) exhibit multiple nano-scale ordering patterns, involving vacancy, cation and magnetic ordering. Soon after the discovery of HTS, Zandbergen et al. observed that the layered structure of YBCO makes this superconductor susceptible to a specific type of cation ordering, namely the insertion of extra copper oxide (CuO) planes. (Nature 1988, 331, 596; incorporated herein by reference in its entirety). The tendency of YBCO to incorporate CuO layers turned out to be of limited practical use, since extended CuO planes provide strong pinning only when the Abrikosov vortices are almost parallel to the film surface. (Specht, et al. Appl. Phys. Lett. 2006, 89, 162510; incorporated herein by reference in its entirety). This is a major reason why the development of YBCO-based superconducting wire has concentrated on the design of artificial pinning centers rather than on utilizing structural chemistry of cuprates. (Maiorov, et al. Nat. Mater. 2009, 8, 398; incorporated herein by reference in its entirety). This approach is, however, reaching its limit, since the excessive density of foreign precipitates, e.g., 5% (mole) of BaZrO₃ or Y₂O₃+BaZrO₃, reduces the critical temperature of the YBCO matrix, negating the advantages from stronger pinning. In addition, the most effective pinning centers, such as BaZrO₃ nanorods, can only be formed at a relatively low YBCO growth rate (Maiorov, 2009), which may be a limitation for large-scale production.

The methods currently used to grow films of complex oxides can be described as adaptations of traditional thin film epitaxy. The substrate serves as a template to transfer the desired crystallographic orientation to the epitaxial layer of a well-known bulk material, YBCO. However, transport properties of YBCO are to a great extent limited by grain boundaries. It is well established that a high-performance YBCO layer requires grain boundary misalignments below about 4°. This has been explained by the anisotropic nature of the YBCO material and strain-induced oxygen depletion of the grain boundary region.

First generation (1G) material, such as Bi₂Sr₂Ca₁Cu₂O₈ (BiSCCO 2212), which is not sensitive to oxygen content, can tolerate higher grain boundary misalignment. This allows for the use of a powder-in-tube method for manufacturing of 1G wire, which is less expensive than methods typically used to produce high-quality YBCO. However, 1G material exhibits high crystalline anisotropy, which limits its application to temperatures below about 40K in magnetic field up to about 1 Tesla. Furthermore, a silver sheath is typically used as the tube, which makes raw materials a significant component of 1G wire cost.

Second generation (2G) YBCO-based wire does not use expensive raw materials, but achieving high performance requires biaxial (both in-plane and out-of-plane) alignment of the YBCO layer, which is typically achieved using either solid-state (metal organic deposition, MOD) or vapor (pulsed laser or metal-organic vapor) epitaxial deposition. Epitaxial deposition requires well-aligned metal substrates buffered with rather complex sequences of oxide layers. This complicated technology results in a very high production cost of 2G wire.

There is therefore a continuing need to develop manufacturing methods that would allow the formation of YBCO materials on films, wires or tapes that can be used for industrial and research use without the drawbacks described above.

### SUMMARY

In view of the above-described problems, needs, and goals, a novel method is disclosed for producing materials that combine the low anisotropy of YBa₂Cu₃O₇ (YBCO) with the grain boundary misalignment tolerance of BiSCCO to make HTS wires, tapes, and other superconducting structures and devices more attractive in the marketplace. Generally, the method has the steps of depositing a precursor layer of average composition YBa₂Cu₃O₇ on a substrate that preferably has a buffer layer of a catalytically active ceria, conversion of the precursor at low oxygen partial pressure of oxygen and annealing the material in oxygen at a lower temperature. A phase of YBCO that is made by this method preferably is insensitive to grain boundary misalignment.

The disclosed method affords the production of a new metastable phase, denoted “SSa,” of YBCO. This phase can be modeled as an A-type of superstructure of YBCO, wherein extra MO planes (M=Y or Ba) are inserted between adjacent Cu—O planes. The new phase maintains its high superconducting transition temperature (T_{c}) while exhibiting a large increase of the critical current density (J_{c}) and irreversibility field (Hᵢᵣᵣ) of the YBCO matrix. In a preferred embodiment, the metastable phase is composed of YBa_{z}CuₓO_{y} material, where 3≦x≦4, 7≦y≦8, and 1.4≦z≦2.5, This material has a symmetry of Amm2, and lattice constants of approximately a=a₀, b=b₀, and c=3c₀, where a₀, b₀, and c₀ are equal to the lattice constants of superconducting YBa₂Cu₃O₇.

New applications of 2G HTS wires, tapes, and other superconducting structures and devices are also contemplated.

It should be understood that the foregoing, being a summary, is necessarily a brief description of some aspects of the invention, which may be better understood with reference to the drawings and the following detailed description.

### BRIEF DESCRIPTION OF THE DRAWINGS

As is common practice in the art, the following figures may not be drawn to scale. Schematic depictions are used to emphasize the particular features of the invention and as a reference for their description. Spectra may be displayed displaced for clarity, with the intensity given in arbitrary units.

FIG. 1 is a plot that shows the behavior of critical current density (J_{c}) with applied magnetic field (H) for YBa₂Cu₃O₇ (YBCO) grown on 100-nm grain size CeO buffer layers (open circles) (CeO-100 samples) and YBCO grown on 20-nm grain size CeO buffer layers (closed circles) (CeO-20 samples).

FIG. 2 is the X-ray diffraction spectra of YBCO grown on 20-nm CeO buffer layers before (open circles) and after (closed circles) after 30-minute annealing at 400° C. in oxygen.

FIG. 3A is the X-ray diffraction spectra of as-grown CeO-20 samples grown at three different oxygen partial pressures: 220 mTorr (lower curve), 160 mTorr (middle curve), and 110 mTorr (upper curve).

FIG. 3B is the X-ray diffraction spectra of annealed CeO-20 samples corresponding to those of FIG. 3A, marked with the respective T_{c}s.

FIG. 4A is the X-ray diffraction spectra of a Ce-20 sample subjected to oxygen annealing at four different temperatures (lower to upper curves): 400° C., 550° C., 600° C., and 700° C.

FIG. 4B is a plot that shows the behavior of J_{c} with H, for the annealed Ce-20 sample of FIG. 4A.

FIG. 4C is a spectrum of reciprocal space maps in the vicinity of the YBCO (001) reflection.

FIG. 5A is the X-ray diffraction spectra near the YBCO (003) reflection after oxygen annealing at 400° C. (black curve) and 700° C. (gray curve).

FIG. 5B is the X-ray diffraction spectra near the YBCO (103) reflection after oxygen annealing at 400° C. (black curve) and 700° C. (gray curve).

FIG. 6A is a transmission electron microscope (TEM) image showing a precipitate of the SSa phase embedded in a matrix of YBCO and Y₂Ba₄Cu₈O₁₆ (Y248).

FIG. 6B is an illustration of the unit cell of YBCO.

FIG. 6C is an illustration of the unit cell of Y248.

FIG. 6D is an illustration of the unit cell of the SSa phase

FIG. 7 shows X-ray rocking curves of the SSa (002) and YBCO (001) reflections.

FIG. 8A is an oxygen K-level X-ray absorption near edge structure (XANES) spectrum of a standard YBCO superconductor in reduced (open circles) and oxidized (closed circles) states.

FIG. 8B is an oxygen K-level XANES spectrum of a catalytically synthesized YBCO derivative superconductor (CeO-20 sample) in reduced (open circles) and oxidized (closed circles) states.

FIG. 9A is a copper K-level XANES spectrum of a standard YBCO superconductor in a reduced (open circles) and oxidized (closed circles) states

FIG. 9B is a copper K-level XANES spectrum of a catalytically synthesized YBCO derivative superconductor in a reduced (open circles) and oxidized (closed circles) states

FIG. 10 is a sketch of the annealing cell used to control the YBCO growth rate.

### DETAILED DESCRIPTION

A novel catalytically synthesized metastable material is provided, which is composed of

YBa_{z}CuₓO_{y}, (1)

where 3≦x≦4, 7≦y≦8, and 1.4≦z≦2.5, with a symmetry of Amm2 and lattice constants of approximately a=a₀, b=b₀, and c=3c₀, where a₀, b₀, and c₀ are equal to the lattice constants of superconducting YBa₂Cu₃O₇.

In a preferred embodiment, the metastable material may be embedded as a phase in a composite superconducting material having a matrix of superconducting YBa₂Cu₃O₇. Preferably, the embedded phase makes up to 90% of the composite material. The composite has a critical current density between 1.6 MA/cm² and 30 MA/cm² at a temperature of approximately 77K. In one exemplary embodiment, the composite has a critical current density of approximately 4.2 MA/cm². It is to be understood, however, that those skilled in the art may develop other combinatorial, structural, and functional modifications without significantly departing from the scope of the instant disclosure.

A catalytically-assisted synthesis of the novel metastable materials is also described. Catalysts are widely utilized to promote reactions in liquid and gaseous phases, but are rarely encountered in solid state synthesis. In this disclosure the concept of catalytically assisted synthesis is used for the fabrication of new metastable materials. A metastable material does not exist in the bulk, because under any growth conditions its critical nucleus is unstable either due to unfavorable thermodynamics or competition from dominant phases. A metastable phase can emerge under two conditions: (i) the substrate is active enough, i.e., it provides nucleation sites with low enough surface energy to make the critical nucleus stable; (ii) the growth conditions are set to suppress the formation of dominant bulk phases, which otherwise would occupy the nucleation sites. If these two conditions are met, new metastable phases may emerge. Remarkably, it has been found that the presence of one such phase, a long-period YBCO derivative denoted below as “SSa,” dramatically improves the superconducting properties of YBCO films.

In a preferred embodiment, the process for making the disclosed superconducting composite material is accomplished by depositing a precursor layer of average composition YBa₂Cu₃O₇ on a catalytically active substrate, processing the precursor layer at low oxygen partial pressure and annealing the material. The processing of the precursor layer is preferably done at temperatures above 700° C. The annealing can be done for approximately 30 minutes in oxygen at a temperature of approximately 400° C. To assist the formation of the epitaxial phases, the substrate preferably includes a buffer layer of ceria (CeO) having an in-plane grain size of approximately 10 nm to 20 nm and in-plane RMS strain exceeding 0.2%. In a preferred embodiment, the substrate has a biaxially aligned surface and the surface of the catalytically active ceria is uniaxially aligned with the superconducting composite material. In an especially preferred embodiment, the ceria buffer is a (001) ceria buffer that may be deposited on single crystal substrates by pulsed laser deposition at a predefined substrate temperature. For example, if the substrate is (001) yttria-stabilized zirconia (YSZ) (CeO-20), its substrate temperature is about 650° C. Alternatively, if the substrate is r-cut sapphire (CeO-100), its substrate temperature is about 700° C. While the ceria buffer may be deposited on the substrate to form any acceptable thickness, it is preferably about 5-30 nm and even more preferably about 15 nm.

The activity of (001) ceria buffer for YBCO epitaxy depends on the ceria buffer grain size and lateral inhomogeneous strain level. Small-grain (<20-nm lateral grain size) strained buffers develop a dense array of nucleation sites generated by threading dislocation outcrops. A buffer with a 20-nm lateral grain size delivers approximately fivefold higher density of YBCO nuclei compared to a buffer with >100-nm grains under identical processing conditions. The penalty associated with the use of small-grain buffers is a relatively high mosaic spread, ˜1°, of the epitaxial YBCO layer, compared to <0.1° when a single crystal wafer is used. However, this is a minor disadvantage considering that the transport superconducting properties are only weakly sensitive to the grain misorientations up to 4°. The ceria grain size may be chosen to deliver a particular density of YBCO nuclei; in general “small” grains have lateral dimensions less than 50 nm and in-plane RMS strain that exceeds 0.2%.

A method of catalyzing the growth of a superconducting cuprate film is also described. According to the disclosed method, a layer having an average composition of the superconducting cuprate is deposited onto a substrate. Without being bound by theory, it is believed that the substrate catalyzes the nucleation of a metastable phase of the superconducting cuprate. The substrate preferably has a layer of catalytically active material having an in-plane grain size less than approximately 50 nm.

The disclosed method of catalyzing the growth of a superconducting cuprate film further includes annealing the as-deposited layer of superconducting cuprate in oxygen at a temperature below a decomposition temperature of the metastable phase, e.g., approximately 600° C. The annealing preferably occurs within 20 to 60 minutes, although about 30 minutes is even more preferable. The annealed cuprate may have a composite of the metastable phase of the superconducting cuprate embedded in a matrix of a stable phase of the superconducting cuprate.

The disclosed method of catalyzing the growth of a superconducting cuprate film further includes controlling the growth rate of the film by controlling the outflow of gaseous HF from the surface of the film. The growth rate of the film is chosen to allow continued growth of the metastable phase. In an exemplary embodiment, the growth rate of the film is approximately 0.5-20 nm/s.

### Example

The examples set forth below also serve to provide further appreciation of the invention but are not meant in any way to restrict the scope of the invention.

YBCO films were grown to a thickness of about 800 nm by a metal-organic deposition (MOD) process from fluorinated precursors. The ceria buffers were deposited on (001) yttria-stabilized zirconia (YSZ) and r-cut sapphire substrates by pulsed laser deposition at a substrate temperature of 650° C. ((001) YSZ, CeO-20 sample) and 700° C. (r-cut sapphire, CeO-100) sample. The substrates were annealed at 1000° C. in flowing oxygen to adjust the lateral grain size. The ceria buffers were characterized by X-ray diffraction using Rigaku Ultima 3 parallel beam optics diffractometer.

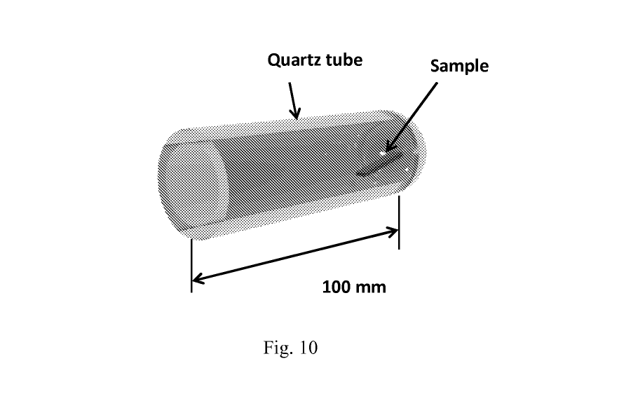

The fluorinated MOD precursor layers were deposited by spin-coating precursors identical to those used in the production of the second-generation superconducting wire. The precursor film had the cation composition of Y:Dy:Ba:Cu=1:0.5:2:3; dysprosium metal was added to enhance pinning at high fields, at the same time Dy addition suppressed formation of Y₂Ba₄Cu₈O₁₆—(Y248)-type stacking faults. The films were converted to (001) YBCO by heat-treatment at 780° C. in an atmosphere comprised of 22 Torr of water vapor and 40-200 mTorr of oxygen. The YBCO growth rate was set at 0.6 nm/s by placing the sample in an annealing cell (FIG. 10).

After the conversion, the samples were annealed in flowing oxygen at 400° C. for 30 minutes. The samples were also subjected to additional annealing at higher temperatures. After each treatment the samples were held for 30 min at 400° C. to restore the oxygen stoichiometry. The critical current density and the critical temperature were then measured by the magnetization method using a Quantum Design SQUID magnetometer.

The X-ray diffraction experiments were carried out at the X-18A beamline of the National Synchrotron Light Source. X-18A is a bending magnet beamline designed for high-flux single-crystal diffraction. Transmission electron microscopy (TEM) characterization was performed using a JEOL 2100 electron microscope.

FIG. 1 is a plot that shows the behavior of critical current density (Jᵣ) with applied magnetic field (H) for YBCO grown on 100-nm grain size CeO buffer layers (open circles) (CeO-100 samples) and YBCO grown on 20-nm grain size CeO buffer layers (closed circles) (CeO-20 samples). FIG. 1 compares the in-field critical current densities of the CeO-100 and CeO-20 0.8-μm samples at 77 K, H∥c-axis orientation. Both samples were processed at conditions optimized for its maximum critical current density, J_{c}, value. Sample CeO-100 represents a typical behavior of a 0.8-μm thick film deposited on a single-crystal substrate or a large grain buffer. The J_{c} of a CeO-100 sample reaches a maximum of ˜2 MA/cm² at p(O₂)=100 mTorr and starts to fall rapidly at lower p(O₂) due to the de-coupling of YBCO grains. In contrast, the small-grain CeO-20 substrate supports high YBCO nucleation at much lower p(O₂) values, thus yielding films having and Hᵢᵣᵣ of 4.2 MA/cm² and 4.5 T, respectively at 65 mTorr. The values of J_{c} and Hᵢᵣᵣ measured by the magnetization method are rather conservative and in general are lower than those obtained by the transport method due to high flux creep at 77 K.

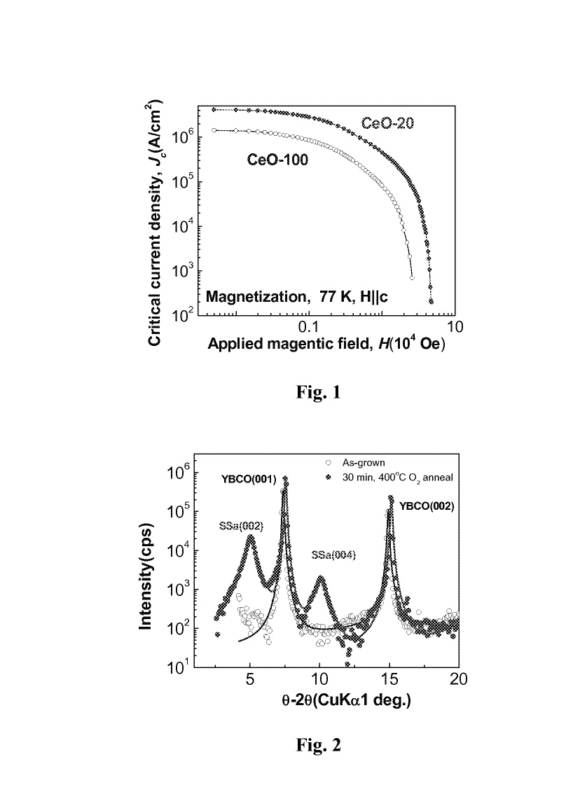

X-ray diffraction performed on the CeO-20 sample reveals a new structural transformation, closely correlated with the enhancement in the performance of this sample. FIG. 2 is the θ-2θ X-ray diffraction spectra of YBCO grown on 20-nm CeO buffer layers before (open circles) and after (closed circles) a 30-minute anneal at 400° C. in oxygen. FIG. 2 shows that the as-grown state has tetragonal symmetry. Oxygen annealing induces formation of a new phase identified by two additional peaks, at 2θ≈5° and 10°, superimposed on a set of (00l) YBCO reflections. In the following description this phase is referred to as an A-type superstructure (SSa) and the corresponding peaks are labeled SSa (002) and SSa (004). The preliminary reflection indexing is based on analogy of this diffraction pattern with that of the YBCO—Y₂Ba₄Cu₈O₁₆ (Y248) mixed films. The new phase appears only in samples processed at oxygen partial pressure below 100 mTorr, rapidly dissipating after high-temperature, high-oxygen partial pressure annealing. This observation confirms that the advantage of the substrate catalysis is most noticeable in the low p(O₂) region, in the proximity of YBCO stability line. While not wishing to be bound by any particular theory, it is believed that under the low p(O₂) growth conditions, the dominant phase, YBCO, becomes less stable, permitting the nucleation sites for the new phases.

The Pearson7 approximations, shown as solid lines in FIG. 2, yield the superstructure peak positions at 2θ=5.048(1) and 10.050(5), which correspond to the d-spacing values of 1.748(1) nm and 0.879(2) nm. From the positions of the YBCO (00l) peaks, the c-axis parameter is 1.168(1) nm, which is in agreement with the well known value of 1.16804(1) nm for fully oxygenated YBCO. The closest reflection of a known YBCO derivative is (002) of Y248 at d=1.36 nm, which makes the SSa structure distinctly different from the well-known derivative phases. The SSa peaks are noticeably broader than the YBCO matrix, suggesting that the SSa domains are small, on the order of 10 nm. Williamson-Hall analysis of the line profile shows that the YBCO matrix can be described as an agglomerate of very large (>1 μm laterally and 350 nm in the c direction) domains with average microscopic out-of-plane tilt (˜0.6°) and relatively low root-mean square (RMS) strain (˜0.3%). The SSa domains appear to be much smaller, ˜10 nm in the c direction and 60 nm in the ab plane.

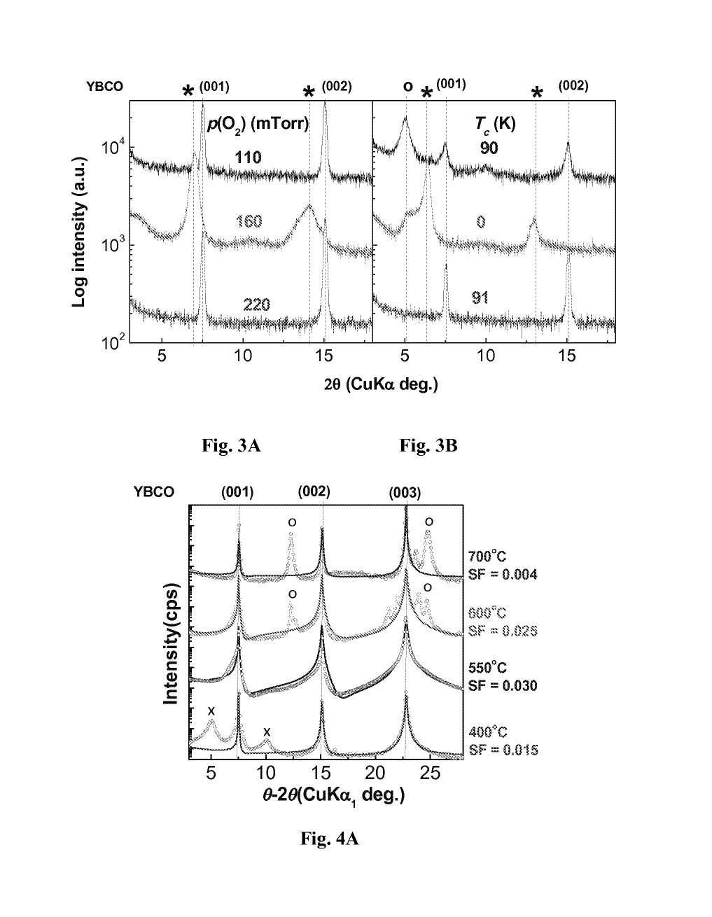

Thinner, 0.1 μm thick films deposited on CeO-20 allow for better identification of the phase composition due to lower film volume and large substrate contribution to the phase formation. FIG. 3A is the X-ray diffraction spectra of as-grown CeO-20 samples grown at three different oxygen partial pressures: 220 mTorr (lower curve), 160 mTorr (middle curve), and 110 mTorr (upper curve), while FIG. 3B shows the X-ray diffraction spectra of annealed CeO-20 samples corresponding to those of FIG. 3A, marked with the respective T_{c}s.

As expected from the p(O₂)-T diagram, growth at high p(O₂) level of 220 mTorr produces the tetragonal YBCO phase (FIG. 3A, lower curve), which after oxygen annealing transforms into the superconducting phase with T_{c}=91 K, as shown in FIG. 3B, lower curve. Reduction of p(O₂) to 160 mTorr results in the formation of a phase with c-axis parameter identical to that of Y248. The Y248 peak positions are marked with an asterisk in FIGS. 3A and 3B. The Y248 phase remains non-superconducting after the annealing procedure. It should be noted that the superconducting Y248 phase (T_{c}=81 K) is stable at p(O₂)>15 Torr at 780° C., an approximately two orders of magnitude higher p(O₂) level than the one employed for this sample. It may be that a high level of structural disorder, evidenced by broadening of (00l) peaks and the absence of high-order reflections, renders “low p(O₂)” Y248 non-superconducting. Further reduction of p(O₂) down to 110 mTorr produces a re-entrant YBCO phase, which has a diffraction signature almost identical to that of standard YBCO. The unique properties of the re-entrant YBCO become apparent after annealing at 400° C. in oxygen (see FIG. 3B). Approximately 90% of the re-entrant YBCO transforms into the SSa phase and the sample becomes superconducting at 90 K. The SSa peak position is marked by an “o” in FIG. 3B. Thus, θ-2θ spectra of the 0.8-μm film, FIG. 2, can be described as the transformation of intermixed re-entrant and standard YBCO phases. Without wishing to be bound by any particular theory, it seems the ability of CeO-20 substrates to nucleate re-entrant YBCO at very low p(O₂) values may be responsible for the phase transformations shown in FIGS. 2 and 3.

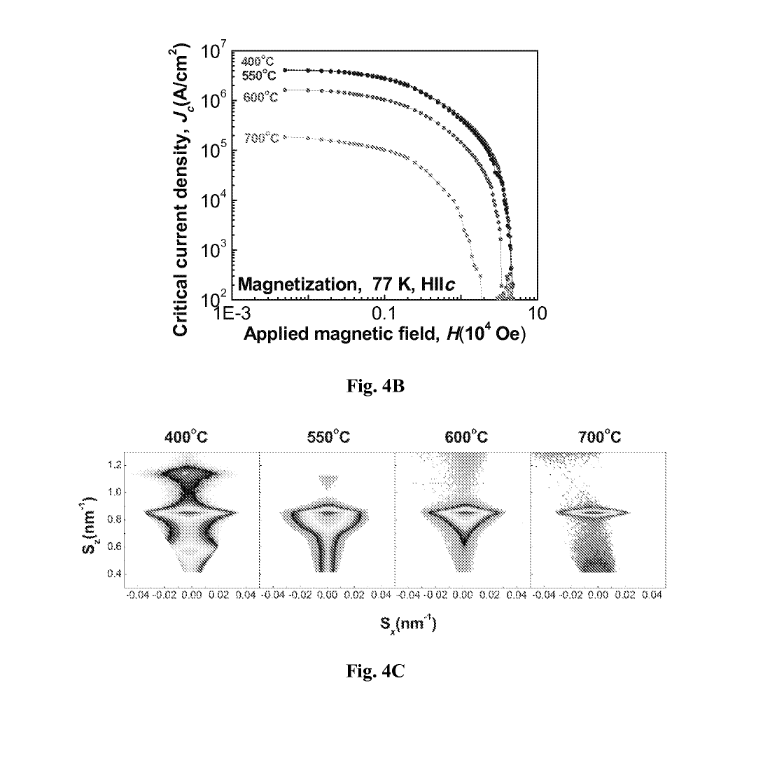

The non-equilibrium nature of the SSa phase becomes apparent after annealing in oxygen at temperatures over 500° C. FIG. 4A is a plot that shows the evolution of the θ-2θ spectra of 0.8-μm thick CeO-20 samples after 30 minutes of oxygen annealing at 550° C., 600° C. and 700° C., respectively. The solid lines are approximations of disordered layered crystal model that was adapted to measure the frequency of Y248 stacking faults (SF) in YBCO films. The approximations show that initially the sample has low density of stacking faults, SF=0.015, which is a typical value for Dy-doped YBCO. The Y248 stacking fault density doubles after annealing at 550° C., at the same time both SSa (002) and SSa (004) peaks dissipate. A rise in the Y248 stacking fault density at 550° C. indicates that SSa starts to decompose into Y248. After the 600° C. step, a new peak appears at 2θ=12.3° and multiple satellites form around the YBCO (003) peak. At 700° C. the satellites transform into two distinct peaks. This transformation may be interpreted as the formation of another, shorter period, B-type superstructure (SSb), which is attributed to be a final decomposition product of SSa. The reflections correspond to d-spacing values of 0.71(2) nm and 0.35(1) nm, respectively. Stacking faults practically disappear upon annealing at 700° C., in agreement with the previous observations.

The structural transformations shown in FIG. 4A correlate with the changes in the in-field J_{c}, plotted in FIG. 4B. Transition from well-defined SSa peaks to a broad low-angle tail after annealing at 550° C. changes the J_{c}(H) curve very little. However, after annealing at 600° C., J_{c} drops by a factor of three. Judging from the diffraction pattern spectrum, annealing at 550° C. completely destroys SSa domains with little effect on the J_{c}. An inspection of the reciprocal space maps in FIG. 4C reveals that even though domains lose long-range order in the c-direction, they still remain small laterally, as indicated by the broad diffuse feature below the YBCO (001) reflection. Decomposition of SSa domains at 600° C. results in the collapse of the broad feature below YBCO (001) peak, which also correlates with the reduction in the J_{c}. At the same time development of a short-period SSb phase, a product of the decomposition of the SSa phase, is observed. The decomposition of the SSa and Y248 stacking faults is completed at 700° C.; after this annealing step J_{c} drops tenfold.

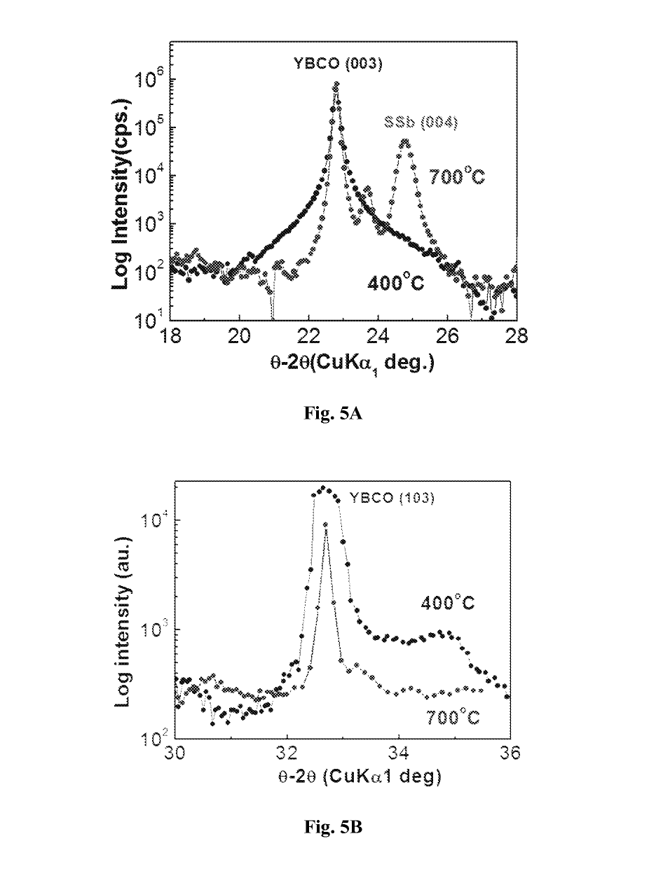

Comparison of the line profiles of the (003) and (103) YBCO reflections before and after the 700° C. treatment shows that normal strain is not affected by the decomposition of the SSa phase, as indicated by the unchanged position and width of (003) reflection (see FIG. 5A). Significant change in the width of the (103) YBCO reflection indicates that the RMS strain produced by the SSa phase has a significant lateral component (see FIG. 5B). Table 1 summarizes the superconducting properties of the CeO-20 samples after the high-oxygen pressure annealing.

TABLE 1
Effect of the high-temperature annealing on superconducting properties
of CeO-20 samples, magnetization measurements, H||c.

| T_{A} (° C.) | J_{c} (MA/cm²), 77 K | Hᵢᵣᵣ (T), 77 K | T_{c} (K) |
|---|---|---|---|
| 400 | 4.2 | 4.5 | 91.8 |
| 550 | 4.1 | 4.4 | 91.7 |
| 600 | 1.6 | 3.3 | 90.1 |
| 700 | 0.2 | 1.3 | 88.7 |

FIG. 5A is X-ray diffraction spectra near the YBCO (003) reflection after oxygen annealing at 400° C. (blue curve) and 700° C. (red curve). The width of the reflection does not change, however the shape of the line is affected by the decomposition of Y248 stacking faults and formation of the SSb phase. FIG. 5B shows X-ray diffraction spectra near the YBCO (103) reflection after oxygen annealing at 400° C. (blue curve) and 700° C. (red curve). Note significant broadening of the profile of the 400° C. sample, which is attributed to lateral strain.

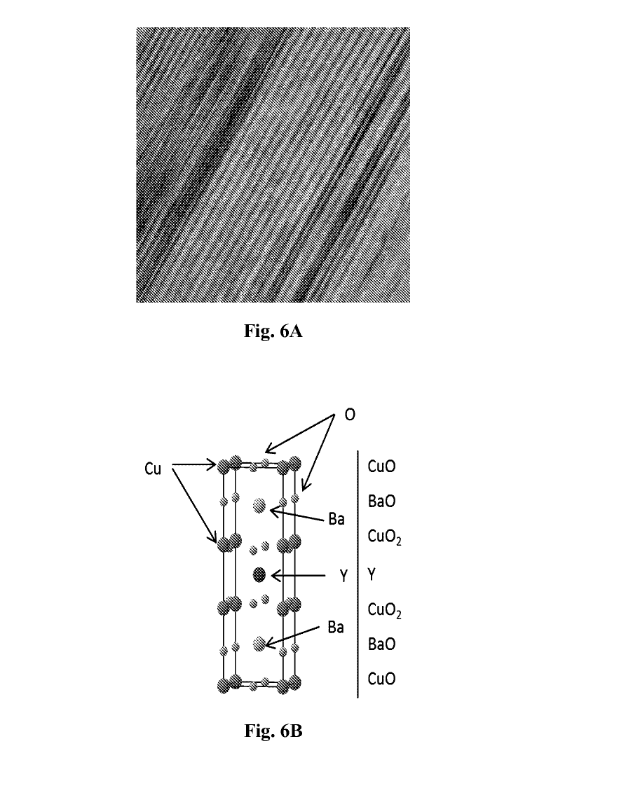

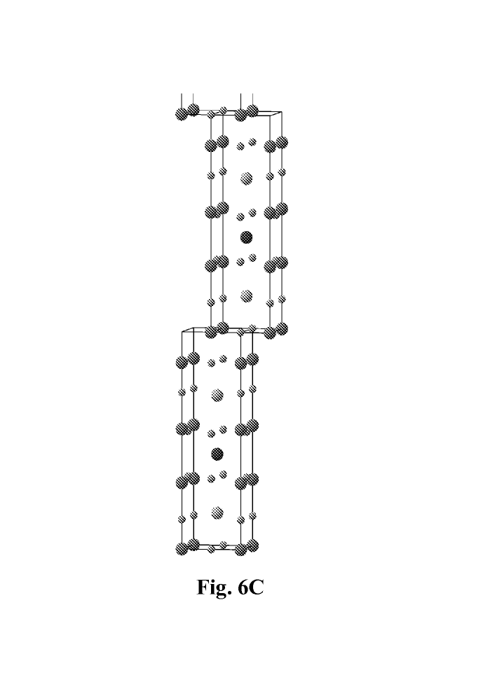

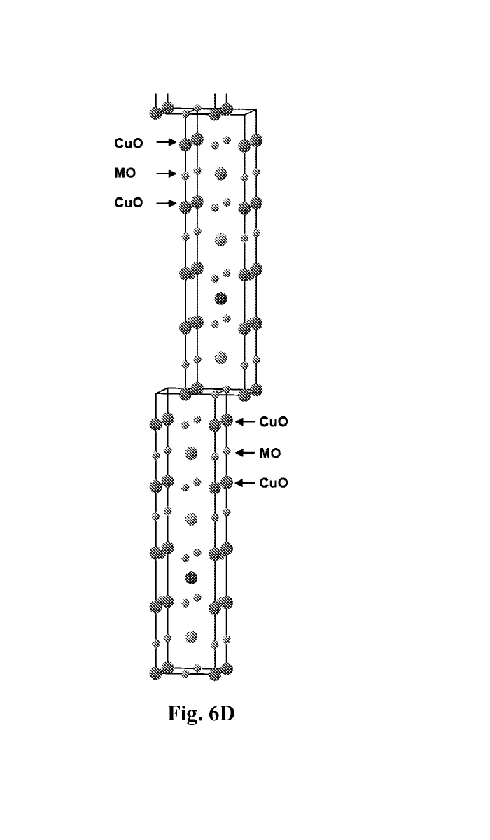

Transmission electron microscopy (TEM) analysis of the CeO-20 samples revealed multiple bright contrast regions embedded in the YBCO matrix. FIG. 6A is a TEM image showing a precipitate of the SSa phase embedded in a matrix of YBCO and Y248. The white rectangle outlines the SSa inclusion. The spacing of fringes along the direction is 1.75 nm, identifying the inclusion as the SSa phase. The structure model is based on an assumption that the SSa phase forms as a result of the re-arrangement of constituent ions, either anions (oxygen), or cations (yttrium, barium, copper) during the low-temperature oxygen anneal of re-entrant YBCO. Since the SSa phase forms at a relatively low temperature (400° C.), the cation motion is limited to a short-range (<1 nm) diffusion. Thus the overall composition of the SSa phase should be close to that of YBCO or Y248. One possible cation arrangement can be realized by insertion of three extra layers of CuO, MO and CuO, where M is the statistical mixture of Y and Ba with 33% Y and 67% Ba.

FIGS. 6B, 6C, and 6D are structure models of YBCO, Y248, and the SSa phase. FIG. 6B is an artist's rendition of the unit cell of YBa₂Cu₃O₇ with c=1.17 nm. FIG. 6C is an artist's rendition of the unit cell of YBa₂Cu₄O₈ with c=2.76 nm. FIG. 6D is an artist's rendition of the unit cell of the SSa phase with c=3.5 nm. The SSa model cell is formed by insertion of two MO—CuO (M=Y_{0.33}Ba_{0.67}) double layers into a Y248 cell. In this model the SSa phase has an A-centered orthorhombic lattice with a=a₀, b=b₀, and c=3c₀, where a₀, b₀, and c₀ are the lattice parameters of YBCO. The structure can also be presented as Y248 with extra MO/CuO double layers in each half cell. The extra double layers break the m x, y, 0 mirror plane, thus reducing the symmetry to Amm2. The calculated XRD intensities based on this model match the experiments well. Currently, it is unclear what structural features of the re-entrant YBCO phase make the low-temperature formation of the SSa phase possible. The difference in the (00l) peak intensity ratio between re-entrant and regular YBCO θ-2θ spectra is too small to attribute the transformation to an inter-layer cation disorder.

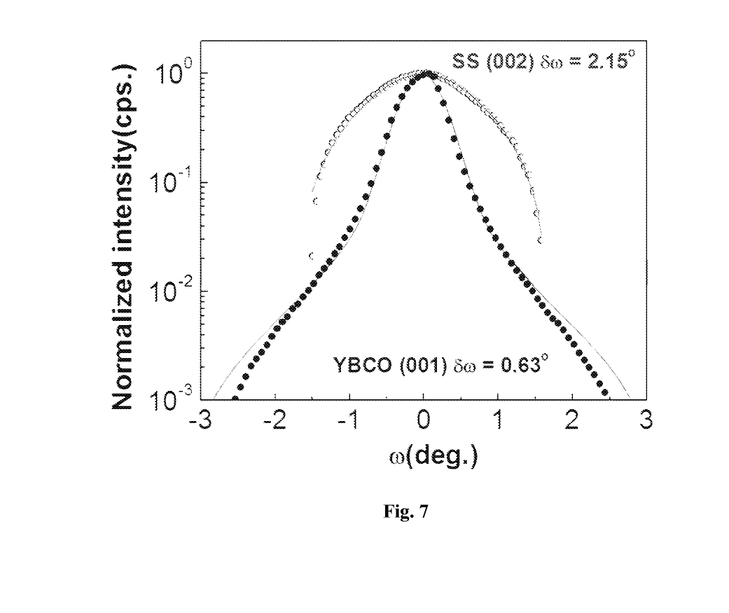

The presence of two metastable long-period YBCO derivatives has been confirmed. Both the derivatives can intercalate the YBCO matrix and provide extra magnetic flux pinning. One of them is the non-superconducting “low-p(O₂)” Y248 phase, which, when diluted in the YBCO matrix, exists as the well known Y248 stacking faults. The effect of stacking faults on J_{c} is well documented: several percent intercalation of YBCO films by Y248 results in a slightly higher J_{c} for H∥c and a much stronger J_{c} enhancement for H∥ab orientations. The insulating nature of “low-p(O₂)” Y248 limits the maximum allowable content of this phase in the YBCO matrix. Using active substrates, like CeO-20, one can change the stacking fault content, however samples with the stacking fault frequency >0.1 are non-superconducting. In contrast, the other YBCO derivative, the previously unknown long-period SSa phase, has a remarkable effect on J_{c} and Hᵢᵣᵣ. The unique features of the SSa phase include strong pinning at the H∥c orientation along with apparent absence of T_{c} degradation even at a very high volume fraction. Direct flux pinning by SSa domains is ruled out because, according to TEM and diffraction data, the domains are plate-like inclusions extending over 50 nm in the ab plane. In comparison, effective artificial pinning centers, such as oxide nano-rods, extend in the ab plane by less than 10 nm. A more likely possibility is that the YBCO-SSa transformation builds internal stress in the film. The stress does not relax due to the very low temperature, 400° C., of the transformation. Indeed, high RMS strain generated by nano-inclusions is thought to be the source of the record pinning force in thin YBCO films. Profile analysis of the YBCO (00l) reflections did not reveal a meaningful change in the normal RMS strain that might be associated with formation and decomposition of the SSa phase. This is not unexpected given that the SSa phase is commensurate with the YBCO matrix in the c-direction, c(SSa)=3×c(YBCO). FIG. 7 is a spectrum of X-ray rocking curves of the SSa (002) (open symbols) and YBCO (001) (closed symbols) reflections. Solid lines are Pearson7 fits used to determine the integral line width. Significantly broader SSa (002) reflections support smaller lateral size of the SSa domains. Analysis of high-order reflections puts the lateral SSa domain size at approximately 50 nm, compared with YBCO lateral grain sizes greater than 1 μm. Presence of the lateral RMS, supported by FIG. 7, implies that formation of the SSa phase exerts lateral deformation of the YBCO matrix.

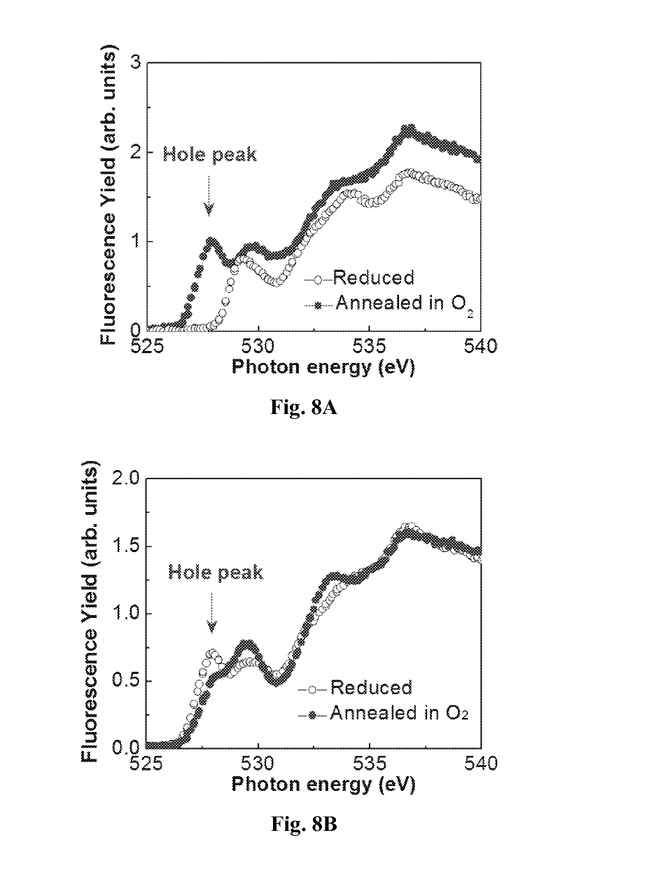

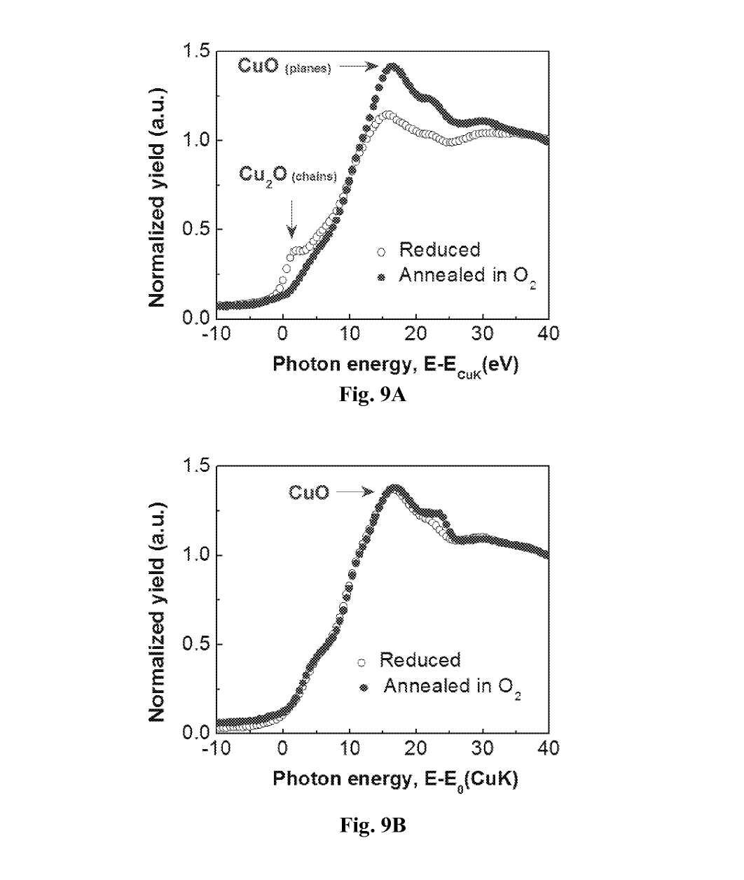

FIG. 8A is a plot of an oxygen K-level X-ray absorption near edge structure (XANES) spectrum of a standard YBCO superconductor in reduced (open circles) and oxidized (closed circles) states, while FIG. 8B is a plot of an oxygen K-level XANES spectrum of a catalytically synthesized YBCO derivative superconductor (CeO-20 sample) in reduced (open circles) and oxidized (closed circles) states. FIG. 9A is a copper K-level XANES spectrum of a standard YBCO superconductor in a reduced (open circles) and oxidized (closed circles) states, and FIG. 9B is a copper K-level XANES spectrum of a catalytically synthesized YBCO derivative superconductor in a reduced (open circles) and oxidized (closed circles) states. An interesting feature of the SSa phase shown by these spectra is the apparent absence of the carrier density change upon oxygenation that is typical of YBCO. In that case, it may allow the design of a superconductor that is less well aligned with the substrate and/or buffer layer on which it is grown. For example, it is possible that only uniaxial alignment may be required to achieve high critical current densities and upper critical magnetic fields while maintaining the high critical superconducting transition temperature of the parent phase.

FIG. 10 is a sketch of the annealing cell used to control the YBCO growth rate. In a particular embodiment, a 13-mm diameter quartz tube was sealed at one end to allow for controllable diffusion of hydrogen fluoride (HF) during growth. The sample, a 3-mm by 10-mm coupon, was placed inside a quartz tube close to the sealed end. This cell design allowed for reproducible and uniform growth rates by controlling the outflow of gaseous HF from the sample's surface. Under certain conditions the YBCO growth rate was maintained at 0.6 nm/s.

While the foregoing description has been made with reference to individual embodiments, it should be understood that those skilled in the art, making use of the teaching herein, may propose various changes and modifications without departing from the invention in its broader aspects. For instance, a relatively simple arrangement of a planar active substrate has been described that was utilized to catalyze the formation of new phases. More complex configurations, for example, three-dimensional arrays of oriented catalytically active nanorods may be utilized in the future to provide greater process flexibility and make the synthesis more scalable. Either the SSa phase alone or SSa-YBCO composites may be used in superconductor devices depending on which are more tolerant to the grain boundary misalignment, leading to relaxation of manufacturing constraints. Use of different catalytically active substrates may lead to other metastable phases that, alone or in conjunction with stable and/or metastable phases, relax these constraints even further. Superconducting structures and devices utilizing such metastable phases and/or composites containing them may include superconducting wires, tapes, magnets, and electronic devices such as SQUIDs and single-flux quantum (SFQ) devices.

All publications and patents mentioned in the above specification are herein incorporated by reference in their entireties. Various modifications and variations of the described materials and methods will be apparent to those skilled in the art without departing from the scope and spirit of the invention. Although the disclosure has been described in connection with specific preferred embodiments, it should be understood that the invention as claimed should not be unduly limited to such specific embodiments. Indeed, those skilled in the art will recognize, or be able to ascertain using the teaching herein and no more than routine experimentation, many equivalents to the specific embodiments of the invention described herein. Such equivalents are intended to be encompassed by the following claims.

1. A material having a composition of YBa_{z}CuₓO_{y}, wherein 3≦x≦4, 7≦y≦8 and 1.4<z<2.5, a symmetry of Amm2, and lattice constants of approximately a=a₀, b=b₀, and c=3c₀, wherein a₀, b₀, and c₀ are equal to the lattice constants of superconducting YBa₂Cu₃O₇.

2. A composite superconducting material having a matrix of superconducting YBa₂Cu₃O₇ and an embedded phase comprising the material of claim 1.

3. The composite superconducting material of claim 2, having a critical current density between 1.6 MA/cm² and 30 MA/cm² at a temperature of approximately 77K.

4. The composite superconducting material of claim 3, having a critical current density of approximately 4.2 MA/cm² at a temperature of approximately 77K.

5. The composite superconducting material of claim 2, wherein up to 90% of the composite material consists of the embedded phase.

6. A method of making a superconducting composite material, the method comprising:
depositing a precursor layer of average composition YBa₂Cu₃O₇ on a catalytically active substrate;
processing the precursor layer at low oxygen partial pressure at a temperature above 700° C.; and
annealing the material in oxygen at a temperature of approximately 400° C.

7. The method of claim 6, wherein the annealing time is approximately 30 minutes.

8. The method of claim 6, wherein the substrate has a biaxially aligned surface.

9. The method of claim 6, wherein the substrate comprises a buffer layer of CeO having an in-plane grain size of approximately 10 nm to 20 nm and in-plane RMS strain exceeding 0.2%.

10. The method of claim 9, wherein the surface of the CeO is uniaxially aligned with the superconducting composite material.

11. A method of catalyzing the growth of a superconducting cuprate film, the method comprising:
depositing a precursor layer having an average composition of the superconducting cuprate onto a substrate,
the substrate operable to catalyze the nucleation of a metastable phase of the superconducting cuprate during the precursor conversion.

12. The method of claim 11, further comprising:
annealing the as-deposited layer in oxygen at a temperature below approximately 600° C. for approximately 30 minutes.

13. The method of claim 12, wherein the annealing temperature is below a decomposition temperature of the metastable phase.

14. The method of claim 12, wherein the annealed cuprate comprises a composite of the metastable phase of the superconducting cuprate embedded in a matrix of a stable phase of the superconducting cuprate.

15. The method of claim 11, wherein the substrate comprises a layer of catalytically active material having an in-plane grain size less than approximately 50 nm and in-plane RMS strain exceeding 0.2%.

16. The method of claim 11, further comprising: controlling the growth rate of the film by controlling the outflow of gaseous HF from the surface of the film.

17. The method of claim 16, wherein the growth rate of the film is chosen to allow continued growth of the metastable phase.

18. The method of claim 16, wherein the growth rate of the film is approximately 0.6 nm/s.
